(19) United States
(12) Patent Application Publication
(10) Pub. No.: US 2016/0163609 A1
(43) Pub. Date: Jun. 9, 2016

(54) METHODS AND APPARATUS FOR TESTING AUXILIARY COMPONENTS IN A MULTICHIP PACKAGE

(71) Applicant: Altera Corporation, San Jose, CA (US)

(72) Inventors: Arifur Rahman, San Jose, CA (US); Chee Hak Teh, Bayan Lepas (MY)

(21) Appl. No.: 14/805,312

(22) Filed: Jul. 21, 2015

Related U.S. Application Data
(60) Provisional application No. 62/087,140, filed on Dec. 3, 2014.

(51) Int. Cl. H01L 21/66; G01R 31/28; H01L 25/065

(52) U.S. Cl. CPC H01L 22/32; H01L 25/0652; G01R 31/2896; G01R 31/2889

(57) ABSTRACT

Ways for testing a multichip package while reducing the required test pin count are provided. The multichip package may include a main die coupled to multiple daughter components. During testing, one of the daughter components may be selected for testing while other daughter components sit idle. The daughter components may receive test signals via a shared path. Dedicated select pins may be used to activate the selected daughter component while placing the unselected components in tristate mode. The selection of daughter components during testing can also be controlled directly using the main die. If desired, general-purpose input-output (GPIO) pins of the main die may be borrowed from the main die to convey the test signals to the selected daughter component during testing. If desired, multiplexing circuitry may also be used to selectively route signals to the daughter components during testing.

This application claims the benefit of provisional patent application No. 62/087,140 filed Dec. 3, 2014 which is hereby incorporated by reference herein in its entirety.

### BACKGROUND

This relates generally to integrated circuit packages, and more particularly, to methods for testing integrated circuit packages with multiple integrated circuit dies.

An integrated circuit package typically includes an integrated circuit die and a substrate on which the die is mounted. The die is often coupled to the substrate through bonding wires or solder bumps. Signals from the integrated circuit die may then travel through the bonding wires or solder bumps to the substrate.

As integrated circuit technology scales towards smaller device dimensions, device performance continues to improve at the expense of increased power consumption. In an effort to reduce power consumption, more than one die may be placed within a single integrated circuit package (i.e., a multi-chip package). As different types of devices cater to different types of applications, more dies may be required in some systems to meet the requirements of high performance applications. Accordingly, to obtain better performance and higher density, an integrated circuit package may include multiple dies arranged laterally along the same plane or may include multiple dies stacked on top of one another.

A multi-chip package can include multiple dies mounted on an interposer. In some arrangements, a primary integrated circuit processor may be coupled to multiple memory integrated circuit chips via the interposer. In general, it may be desirable to test and debug the memory chips prior to normal operation. In scenarios in which the memory chips support high bandwidth communications, the number of external pins that must be bonded out for test and debug can be significant and can multiply with the number of memory chips that are included within the multichip package, which can severely limit the number of general-purpose input-output (GPIO) pins that is available to the primary processor during normal operation.

It is within this context that the embodiments described herein arise.

### SUMMARY

In accordance with an embodiment, a multichip package is provided that includes an integrated circuit, a plurality of auxiliary integrated circuit (IC) components coupled to the integrated circuit, and a test input-output (IO) pin that is coupled to at least two of the auxiliary integrated circuit components and that is used to convey test signals to the at least two auxiliary integrated circuit components during testing. In certain arrangements, the multichip package may also include an interposer on which the integrated circuit and the auxiliary integrated circuit components are mounted.

In one suitable arrangement, the multichip package may also include a plurality of dedicated test pins each of which is coupled to and conveys a corresponding select signal to a respective one of the auxiliary integrated circuit components to place each of the auxiliary integrated circuit components in a selected one of an active test mode and a tristate mode.

In another suitable arrangement, the test IO pin may be a general-purpose input-output (GPIO) pin of the integrated circuit. The GPIO pin may be borrowed from the integrated circuit so that the test signals may be conveyed to the auxiliary components via the GPIO pin during testing. The GPIO pin may be returned to the integrated circuit after testing so that active user data signals may be conveyed to the integrated circuit during normal operating of the multichip package. In certain embodiments, a first portion of the auxiliary integrated circuit components may be coupled to a first set of GPIO pins of the integrated circuit, whereas a second portion of the auxiliary integrated circuit components that are different than the first portion may be coupled to a second set of GPIO pins of the integrated circuit that is different than the first set.

In yet another suitable arrangement, multiplexing circuitry that is interposed between the auxiliary integrated circuit components and the test input-output pin may be used to route the test signals to a selected auxiliary component. The multiplexing circuitry may be formed within the interposer or as part of the integrated circuit. If desired, the integrated circuit may be used to select which auxiliary component is currently being tested by sending control signals from the integrated circuit directly to the auxiliary components.

Further features of the present invention, its nature and various advantages will be more apparent from the accompanying drawings and the following detailed description.

### BRIEF DESCRIPTION OF THE DRAWINGS

FIG. 1 is a diagram showing illustrative test equipment that can be used to test and debug a multichip package in accordance with an embodiment.

FIG. 2 is a diagram of an illustrative multichip package that includes a main integrated circuit die coupled to multiple auxiliary chip stacks via embedded physical layer interface circuitry in accordance with an embodiment.

FIG. 3 is a cross-sectional side view of an illustrative multichip package having an interposer in accordance with an embodiment.

FIG. 4 is a cross-sectional side view of an illustrative multichip package in accordance with an embodiment.

FIG. 5 is a diagram illustrating how test pins for each auxiliary circuit under test (CUT) can be ganged together to minimize loss of input-output (IO) pins in accordance with an embodiment.

FIG. 6 is a diagram illustrating how test pins for each auxiliary CUT can be ganged together with a set of general-purpose IO (GPIO) pins associated with the main die in a multichip package in accordance with an embodiment.

FIG. 7 is a diagram illustrating how test pins for each auxiliary CUT can be ganged together with different sets of GPIO pins for enabling parallel testing in accordance with an embodiment.

FIG. 8 is a diagram of illustrative multiplexing circuitry that is implemented in an active interposer to minimize pin count in accordance with an embodiment.

FIG. 9 is a diagram of illustrative multiplexing circuitry that is implemented on the main die to reduce external pin count in accordance with an embodiment.

FIG. 10 is a flow chart of illustrative steps involved in testing multiple auxiliary CUTs within a multichip package in accordance with an embodiment.

### DETAILED DESCRIPTION

Embodiments of the present invention relate to integrated circuits, and more particularly, to integrated circuit packages that include multiple integrated circuit dies.

As integrated circuit fabrication technology scales towards smaller process nodes, it becomes increasingly challenging to design an entire system on a single integrated circuit die (sometimes referred to as a system-on-chip). Designing analog and digital circuitry to support desired performance levels while minimizing leakage and power consumption can be extremely time consuming and costly.

One alternative to single-die packages is an arrangement in which multiple dies are placed within a single package. Such types of packages that contain multiple interconnected dies may sometimes be referred to as systems-in-package (SiPs), multi-chip modules (MCM), or multi-chip packages. Placing multiple chips (dies) into a single package may allow each die to be implemented using the most appropriate technology process (e.g., a memory chip may be implemented using the 28 nm technology node, whereas the radio-frequency analog chip may be implemented using the 45 nm technology node), may increase the performance of die-to-die interface (e.g., driving signals from one die to another within a single package is substantially easier than driving signals from one package to another, thereby reducing power consumption of associated input-output buffers), may free up input-output pins (e.g., input-output pins associated with die-to-die connections are much smaller than pins associated with package-to-board connections), and may help simplify printed circuit board (PCB) design (i.e., the design of the PCB on which the multi-chip package is mounted during normal system operation).

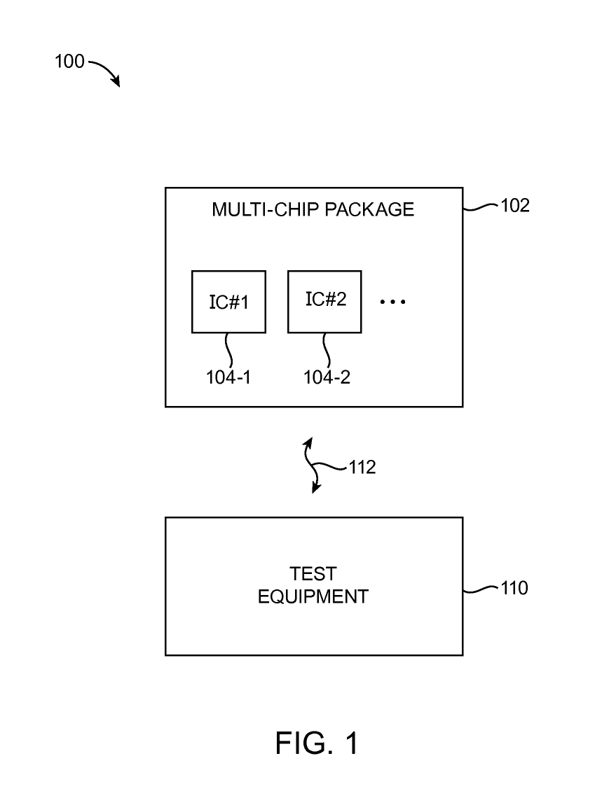

In general, it may be desirable to be able to performing testing on one or more dies within a multichip package to ensure that the dies on the multichip package are functioning properly. FIG. 1 is a diagram of an illustrative test system 100 that includes test equipment 110 for testing and/or debugging a multichip package such as package 102. As shown in FIG. 1, multichip package 102 may include multiple integrated circuit (IC) dies including at least a first IC 104-1 and a second IC 104-2. The integrated circuit dies on package 102 may be any suitable integrated circuit such as programmable logic devices, application specific standard products (ASSPs), and application specific integrated circuits (ASICs). Examples of programmable logic devices include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

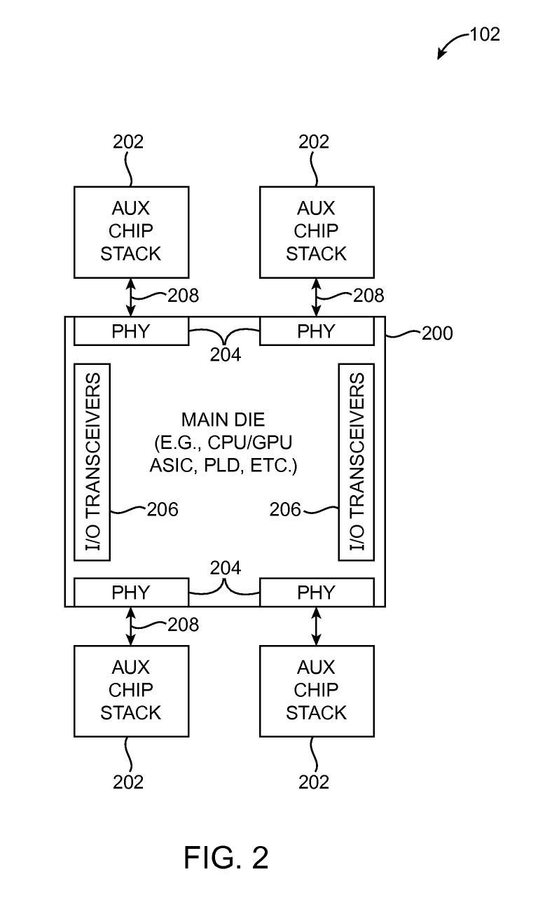

Test equipment 110 may communicate with multichip package 102 via path 112. In particular, one or more test pins (e.g., bonded-out external package pins) that are part of package 102 may be used to interface directly with test equipment 110 during test and debug operations. It is generally desirable to minimize the number of dedicated test pins so that more input-output (IO) pins can be made available during normal operation of the multichip package. Examples of this are described below in connection with at least FIGS. 2-9 in accordance with various embodiments of the present invention.

FIG. 2 shows one suitable arrangement of multichip package 102. As shown in FIG. 2, package 102 may include an integrated circuit 200 that is coupled to multiple auxiliary integrated circuit devices 202. Die 200, which may be a central processing unit (CPU), a graphics processing unit (GPU), an ASIC, a programmable device, or other suitable integrated circuit, may serve as a primary processor for package 102 and may therefore sometimes be referred to herein as the main die. The auxiliary components 202 that communicate with the main die are sometimes referred to as “daughter” dies.

Integrated circuit 200 may include transceivers and/or other input-output (IO) components 206 for interfacing with devices external to package 102. Main integrated circuit 200 may also include physical-layer (PHY) interface circuitry such as PHY circuits 204 that serve to communicate with the auxiliary components 202 via inter-die traces 208.

In accordance with some embodiments, each auxiliary component 202 may be a memory chip stack (e.g., one or more memory devices stacked on top of one another) that is implemented using random-access memory such as static random-access memory (SRAM), dynamic random-access memory (DRAM), low latency DRAM (LLDRAM), reduced latency DRAM (RLDRAM) or other types of volatile memory. If desired, each auxiliary memory chip stack 202 may also be implemented using nonvolatile memory (e.g., fuse-based memory, antifuse-based memory, electrically-programmable read-only memory, etc.). Each auxiliary component 202 that serves as a memory chip stack is sometimes referred to herein as a “memory element.”

Each circuit 204 may serve as a physical-layer bridging interface between an associated memory controller on main die 200 (e.g., a non-reconfigurable “hard” memory controller or a reconfigurable “soft” memory controller logic) and one or more high-bandwidth channels that is coupled to an associated memory element 202.

Each instantiation of the PHY circuit 204 can be used to support multiple parallel channel interfaces such as the JEDEC JESD235 High Bandwidth Memory (HBM) DRAM interface or the Quad Data Rate (QDR) wide IO SRAM interface (as examples). Each of the parallel channels can support single data rate (SDR) or double data rate (DDR) communications. If desired, PHY circuit 204 may also be used to support a plurality of serial IO channel interfaces.

Each PHY circuit 204 that is capable of supporting a wide array of channel interfaces may be implemented as a hard intellectual property (IP) block that is embedded within device 200 and may sometimes be referred to herein as a Universal Interface Block or UIB. The example described herein in which each UIB 204 is used to interface with a memory stack is merely illustrative and does not serve to limit the scope of the present invention. In general, UIB 204 may be used to interface with any suitable electronic component coupled to system 102. Configured in this way, UIB 204 enables low-latency, high random transaction rate (RTR) throughput that is at least equal to external SRAM performance and/or high capacity storage compatible with external RLDRAMs or DDRx DRAMs with reduced power and zero IO footprint.

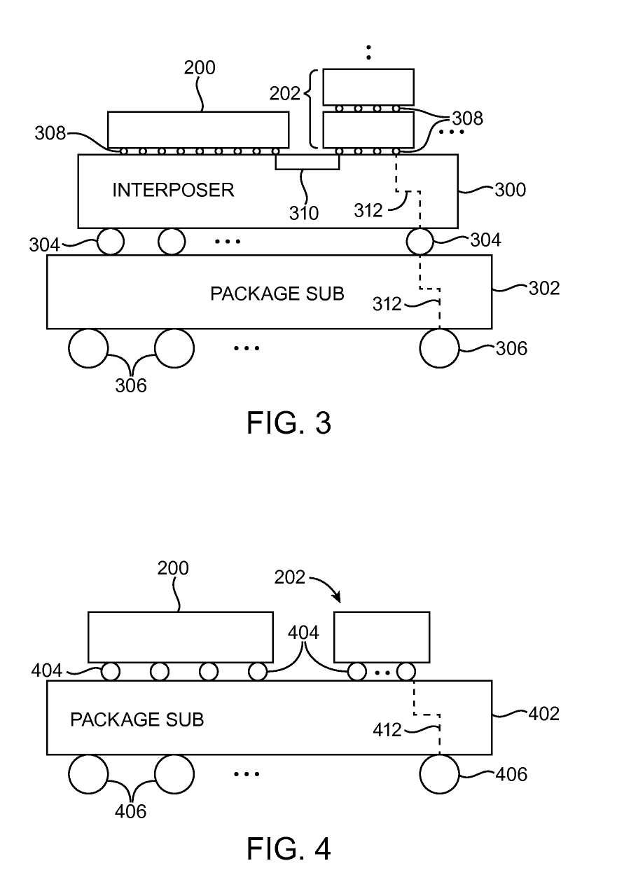

Devices 200 and 202 may be mounted on an intermediary substrate such as a silicon interposer or other organic substrate carrier (see, e.g., FIG. 3). As shown in FIG. 3, main die 200 and chip stack 202 may be mounted on a common interposer 300. Main die 200 may communicate directly with chip stack 202 via microbumps 308 and one or more communications path 310 formed in interposer 300. Path(s) 310 may represent one of the inter-die traces 208 of FIG. 2.

Referring still to FIG. 3, interposer 300 may be coupled to a package substrate 302 via bumps 304. Bumps 304 that interface directly with package substrate 302 may sometimes be referred to as controlled collapse chip connection (C4) bumps or flip-chip bumps and may each have a diameter of 100 μm (as an example). Generally, flip-chip bumps 304 (e.g., bumps used for interfacing with off-package components) are substantially larger in size relative to microbumps 308 (e.g., bumps used for interfacing with other dies within the same package). An array of solder balls 306 (sometimes referred to collectively as a ball grid array or BGA) may be formed at the bottom surface of package substrate 302.

In another suitable arrangement, devices 200 and 202 may be mounted on a laminate substrate and may communicate with one another via local interconnects embedded in the laminate substrate (see, e.g., FIG. 4). As shown in FIG. 4, main die 200 and chip stack 202 may be mounted on a common substrate 402. Main die 200 may communicate directly with chip stack 202 via flip-chip (C4) bumps 404 and one or more communications paths within intermediary package substrate 402. An array of solder balls 406 (solder balls arranged in a BGA configuration) may be formed at the bottom surface of package substrate 402. The arrangements in FIGS. 3 and 4 in which multiple dies are mounted on a common intermediary substrate within a single package may sometimes be referred to as a “2.5D” stacked die arrangement.

FIGS. 3 and 4 illustrate how auxiliary component 202 may be bonded out for testing. In FIG. 3, one of microbumps 308 associated with stack 202 may be bonded out to external solder ball 306 via dotted path 312. Solder ball 306 that can be used to transfer test signals to and from auxiliary component 202 via path 312 may therefore serve as a test pin. Similarly, one of bumps 404 associated with daughter component 202 in FIG. 4 may be bonded out to external solder ball 406 via dotted path 412. Solder ball 406 that can be used to transfer test signals to and from auxiliary component 202 via path 412 may be configured as a test pin. In scenarios in which a multichip package includes multiple high bandwidth memory (HBM) stacks 202, the number of such test pins that need to be bonded out can increase significantly and can severely limit the number of usable GPIO that is available to the main die.

For many applications, a substantial reduction in the number of available GPIO pins is undesirable since the test/debug pins that are bonded out are used primarily for testing and do not have any practical use during normal operation. It may therefore be desirable to provide an efficient way of testing/debugging the auxiliary stacks 202 in a multichip package without excessively limiting the amount of available GPIO pins during normal operation.

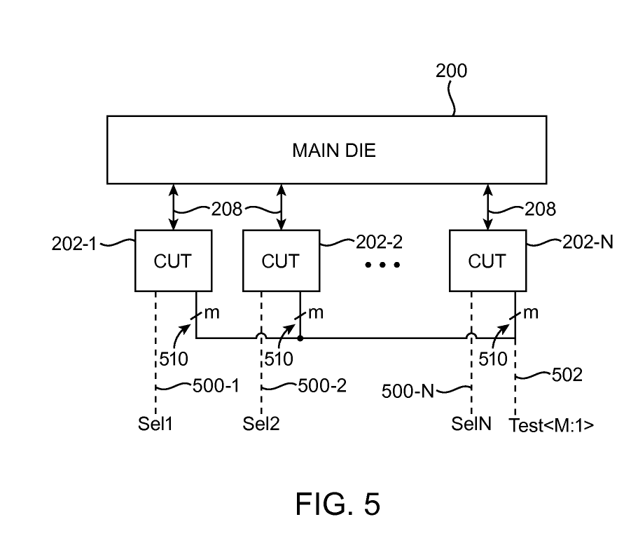

FIG. 5 shows one suitable arrangement in which test pins for each auxiliary component under test (or “CUT”) 202 can be ganged together to minimize the loss of IO pins. As shown in FIG. 5, main die 200 may be coupled to N circuits under test (e.g., CUT 202-1, CUT 202-2, . . . , and CUT 202-N) via inter-die paths 208. Data signals, address signals, clock signals, command signals, and other control signals may be conveyed between the main die 200 and the auxiliary chip stacks 202 via paths 208.

Each CUT 202 may have m test ports 510 that are all shorted together and coupled to path 502. Path 502 may be bonded out to a set of shared test pins for the package substrate. Each CUT 202 may receive a respective select signal via a dedicated select pin 500. In the example of FIG. 5, CUT 202-1 may receive select signal Sel1 via dedicated package test pin 500-1; CUT 202-2 may receive select signal Sel2 via dedicated package test pin 500-2; . . . ; and CUT 202-N may receive select signal SelN via dedicated package test pin 500-N. Only one of the select signals Sel1-SelN may be asserted to activate a single one of the CUTs 202 at any given point in time during testing (i.e., only one memory chip stack 202 can be activated through use of the select pins). A deasserted select signal may place the corresponding CUT in a tri-state mode during which test ports 510 associated with that CUT are not actively driven. Configured in this way, test signals Test<M:1> will only be conveyed to the selected/activated CUT via test ports 510 on path 502 while all remaining CUTs are in an idle state. In this particular example, path 502 may be an m-bit wide signal path that conveys the m-bit test signals in parallel to the selected CUT. This is merely illustrative. If desired, the test signals may instead be serially driven via a one bit wide path to the selected CUT.

For example, consider a scenario in which a multichip package includes a main die that is coupled to four HBM DRAM memory stacks 202. Each memory stack 202 may require a total of 60 IO pins, one of which serves as the select pin and 59 of which serve as the test pins. Following the arrangement of FIG. 5, four dedicated pins may be bonded out for the four DRAM stacks 202, whereas the 59 test pins associated with each of the four DRAM stacks 202 may be ganged together and may receive Test<59:1> via path 502. In this way, only 63 pins (4 dedicated select pins and 59 shared test pins) are bonded out for testing instead of 240 pins (4*60), thereby reducing the required number of test pins by a factor of four (as an example).

If desired, more than one CUT 202 may be activated for parallel testing (e.g., by asserting more than one of the select signals). For example, signals Sel1 and Sel2 may be simultaneously asserted to enable parallel testing of both CUTs 202-1 and 202-2.

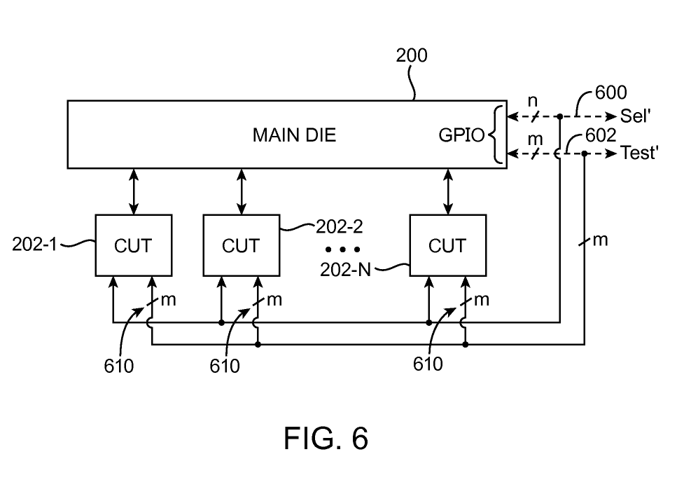

FIG. 6 shows another suitable arrangement in which test pins for each auxiliary CUT 202 can be ganged together with a set of general-purpose IO (GPIO) pins to minimize the lost pin count. The GPIO pins (i.e., pins 600 and 602) may serve as GPIO pins for the main die 200. As shown in FIG. 6, main die 200 may be coupled to N CUTs 202. Each CUT 202 may have m test ports 610 that are all shorted together and coupled to GPIO pins 602. Each CUT 202 may also receive a respective one of select signals Sel′ via a dedicated GPIO pin 600.

As in the example of FIG. 5, only one of the N CUTs may be activated by asserting one of signals Sel′. Configured in this way, test signals Test′ will only be conveyed to the selected/activated CUT while all remaining CUTs are placed in tri-state mode.

For example, consider a scenario in which a multichip package includes a main die that is coupled to four HBM DRAM memory stacks 202. Each memory stack 202 may require a total of 60 IO pins, one of which serves as the select pin and 59 of which serve as test pins. Following the arrangement of FIG. 6, four GPIO pins 600 may be bonded out for the four DRAM stacks 202, whereas 59 GPIO 602 pins may be shorted to each of the four DRAM stacks 202 and may receive test signals Test′ during testing.

During testing, a selected one of four signals Sel′ may be asserted on GPIO pins 600 while test signals are conveyed between the one activated CUT and the test equipment via GPIO pins 602. During normal operation, all four select signals Sel′ are deasserted. However, since the four CUTs 202 are all placed in tri-state mode, the 59 GPIO pins 602 may be actively used by main die 200 during normal operation (i.e., for transmitting output signals and/or receiving inputs signals). In other words, the CUTs 202 are only temporarily “borrowing” some of the GPIO pins (e.g., pins 602) from the main die 200 during testing, and the borrowed GPIO pins may be made available to the main die during normal operation, thereby reducing the number of external test pins that are only functional during testing. In this way, only four GPIO pins are unusable during normal mode instead of 240 pins (4*60), thereby reducing the required number of test pins by a factor of 60 (as an example).

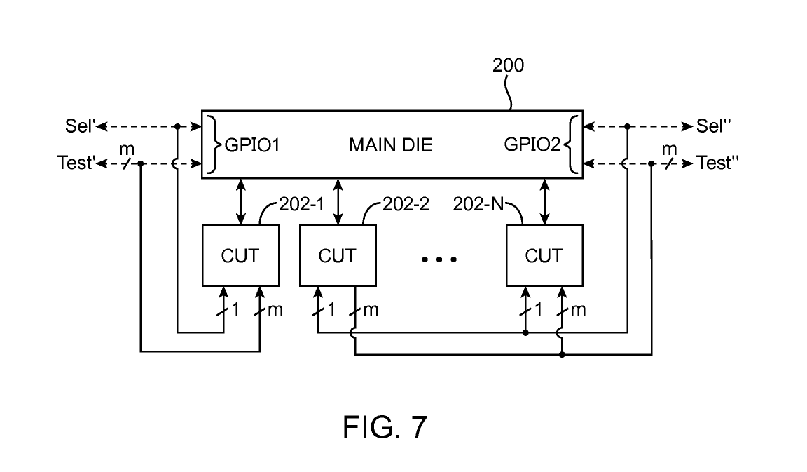

In another suitable arrangement, the CUTs may be coupled to different sets of GPIO pins to help minimize loss of IO pins (see, e.g., FIG. 7). As shown in FIG. 7, a first group of one or more CUTs (e.g., CUT 202-1) may be coupled to a first set of GPIO pins (labeled as “GPIO1”), whereas a second group of one or more CUTs (e.g., CUTs 202-2, 202-3, . . . , and 202-N) may be coupled to a second set of GPIO pins (labeled as “GPIO2”). The pins GPIO1 and GPIO2 may serve as GPIO pins for main die 200. The GPIO1 pins may provide a select signal(s) Sel′ and test signals Test′ to the first group of CUTs, whereas the GPIO2 pins may provide select signals Sel″ and test signals Test″ to the second group of CUTs.

Only one CUT in the first group of CUTs can be activated during testing by controlling Sel′ (while other CUTs, if any, are placed in tri-state mode). Similarly, only one CUT in the second group of CUTs can be activated by controlling Sel″ (while other CUTs, if any, are placed in tri-state mode). The use of multiple sets of GPIOs can allow simultaneous testing of multiple CUTs (e.g., a first CUT in the first group can be tested in parallel with a second CUT in the second group by asserting one of signals Sel′ and one of signals Sel″ at any given point in time). The example of FIG. 7 in which two sets of GPIOs are coupled to the CUTs is merely illustrative and does not serve to limit the scope of the present invention. If desired, the CUTs 202 may be coupled to three or more different sets of GPIOs associated with the main die to enable additional parallel testing.

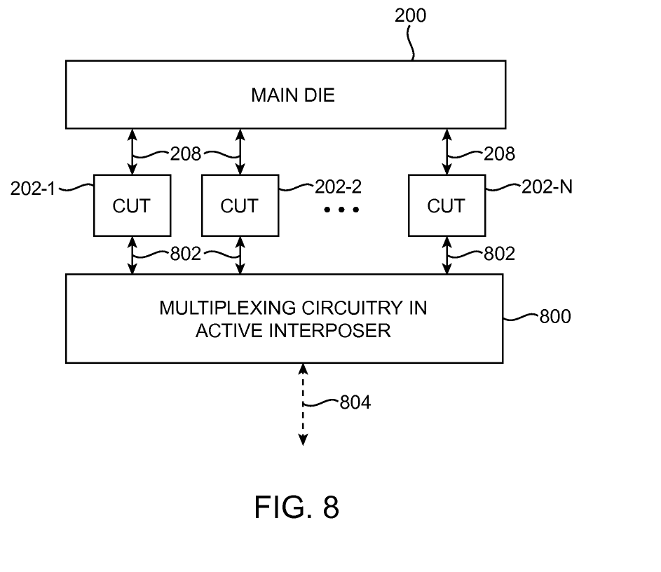

FIG. 8 shows yet another suitable arrangement in which reduction of test pin count is achieved via use of multiplexing circuitry. As shown in FIG. 8, the auxiliary CUTs 202 may be coupled to multiplexing circuitry 800 that is formed in an active interposer via paths 802 (as an example). Multiplexing circuitry 800 may be configured to route signals between a selected one of the circuits under test (CUTs) and external test equipment that is connected to circuitry 800 via path 804.

For example, consider a scenario in which a multichip package includes a main die that is coupled to five HBM DRAM memory stacks 202. Each memory stack 202 may require a total of 55 IO pins. Following the arrangement of FIG. 8, each of memory stacks 202 may be coupled to multiplexing circuitry 800, and only 55 test pins may be bonded out via dotted path 804. Multiplexing circuitry 800 selectively provides test input signals from path 804 to a selected one or more of CUTs 202. Multiplexing circuitry 800 may also provide test output signals from a selected one of CUTs 202 to path 804. Thus, multiplexing circuitry 800 may function as a multiplexer and/or as a de-multiplexer. Configured in this way, the number of required test signals is reduced by a factor that is equal to the number of memory stacks, because each of the memory stacks 202 uses the same path 804 for testing via multiplexing circuitry 800. If desired, additional select pins may be bonded out for tri-stating the CUTs that are not currently being tested. In some embodiments, main 200 may be responsible for sending appropriate select signals to the CUTs via inter-die paths 208, thereby obviating the need for bonded-out select pins.

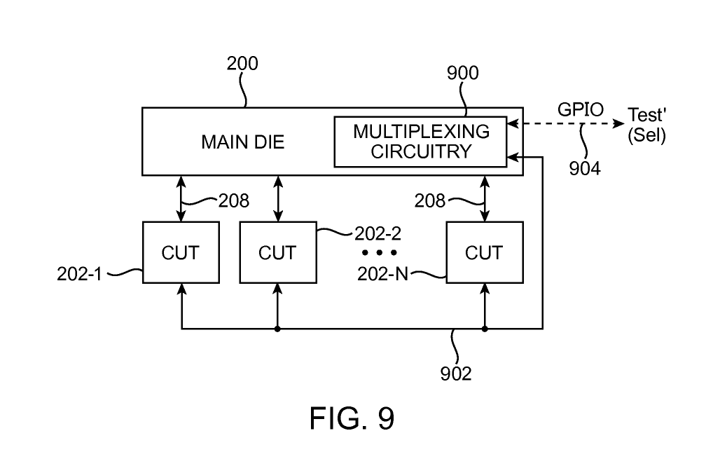

In another suitable arrangement, multiplexing circuitry may instead be implemented on the main die (see, e.g., FIG. 9). As shown in FIG. 9, main die 200 may include multiplexing circuitry 900 that is coupled to each of the N auxiliary CUTs via on-packaging routing paths 902 (e.g., routing paths within an interposer structure or other intermediary substrate). Multiplexing circuitry 900 may be configured to route signals between a selected one of the circuits under test and external test equipment that is connected to circuitry 900 via GPIO pins 904.

For example, consider a scenario in which a multichip package includes a main die that is coupled to six memory stacks 202. Each of the six memory stacks 202 may require a total of 40 IO pins. Following the arrangement of FIG. 9, each of memory stacks 202 may be coupled to multiplexing circuitry 900, and only 40 GPIO pins may be used to receive test signals Test′ during testing.

During normal operation, multiplexing circuitry 900 may be configured to route user signals between the core circuitry of main die 200 and GPIO pins, which effectively decouples the CUTs from the GPIO pins. In other words, the CUTs 202 are only temporarily “borrowing” some of the GPIO pins 904 from the main die 200 during testing, and the borrowed GPIO pins may be made available to the main die during normal operation, thereby reducing the number of external test pins that are only functional during testing. Configured in this way, the number of required test signals is reduced to zero since there are no dedicated test pins that are only active during testing and idle during normal operation.

If desired, additional GPIO select pins (e.g., GPIO pins that receive signal Sel) may be used for tri-stating the CUTs that are not currently being tested. In certain embodiments, main 200 may be responsible for sending appropriate select signals to the CUTs via inter-die paths 208, thereby obviating the need for GPIO pins that are dedicated to receiving select signals.

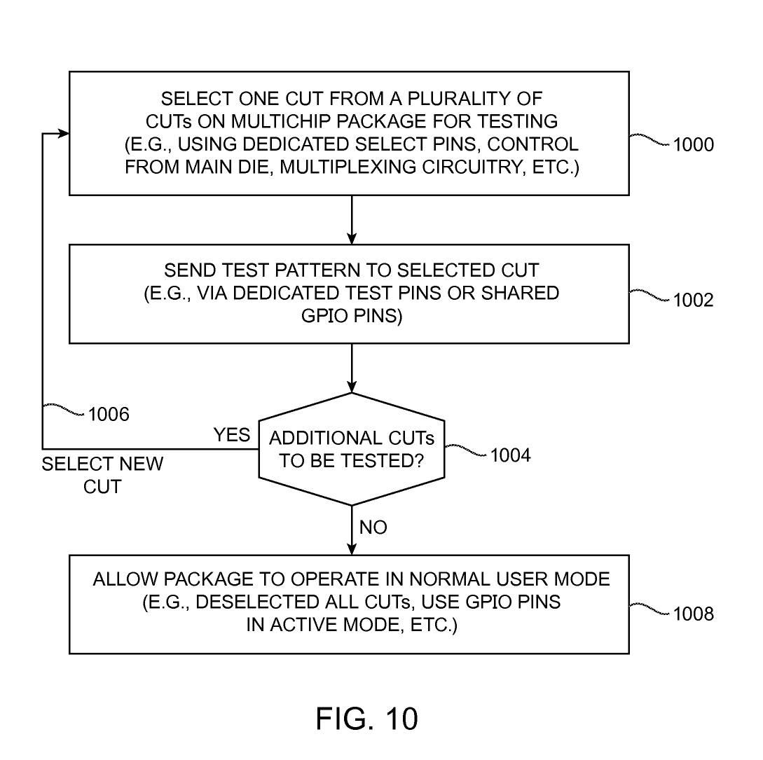

FIG. 10 is a flow chart of illustrative steps involved in testing a multichip package of the type described in connection with FIGS. 1-9. At step 1000, a CUT may be selected from a plurality of CUTs on the multichip package for testing. The CUT may be chosen via use of dedicated select pins, via control from the main die, via use of multiplexing circuitry, or via other suitable selection means.

At step 1002, a desired pattern of test signals may be sent from the test equipment (FIG. 1) to the selected CUT either via dedicated test pins (see, e.g., the embodiments of FIGS. 5 and 8) or via borrowed GPIO pins (see, e.g., the embodiments of FIGS. 6, 7, and 9). When testing of the selected circuit under test has been completed, the test equipment may determine whether there are any additional CUTs that still need to be tested at step 1004. If so, processing may loop back to step 1000 (as indicated by path 1006) to select a new CUT for testing.

If at least one of the CUTs fails testing, that CUT or that entire multichip package may be further tested to determine whether that package can be repaired or salvaged. If it is determined that the package cannot be repaired, that CUT or that entire package may be discarded. If all auxiliary components have successfully passed testing, the multichip package may be shipped to customers and may be allowed to be operated in normal user mode (step 1008). During normal user mode, the select pins (if any) may all be deasserted to deselect all CUTs for testing. In scenarios in which GPIOs pins have been temporarily borrowed during testing, those GPIO pins are placed in active mode to convey user signals during normal operation.

Although the methods of operations were described in a specific order, it should be understood that other operations may be performed in between described operations, described operations may be adjusted so that they occur at slightly different times or described operations may be distributed in a system which allows occurrence of the processing operations at various intervals associated with the processing, as long as the processing of the overlay operations are performed in a desired way.

The foregoing is merely illustrative of the principles of this invention and various modifications can be made by those skilled in the art without departing from the scope and spirit of the invention. The foregoing embodiments may be implemented individually or in any combination.

What is claimed is:

1. A multichip package, comprising:
an integrated circuit;
a plurality of auxiliary integrated circuit components coupled to the integrated circuit; and
a test input-output (IO) pin that is coupled to at least two auxiliary integrated circuit components in the plurality of auxiliary integrated circuit components and that is used to convey test signals to the at least two auxiliary integrated circuit components during testing.

2. The multichip package defined in claim 1, wherein the plurality of auxiliary integrated circuit components comprises a plurality of memory chip stacks.

3. The multichip package defined in claim 1, further comprising:
an interposer on which the integrated circuit and the plurality of auxiliary integrated circuit components are mounted.

4. The multichip package defined in claim 1, further comprising:
a plurality of dedicated test pins each of which is coupled to and conveys a corresponding select signal to a respective one of the plurality of auxiliary integrated circuit components to place each of the plurality of auxiliary integrated circuit components in a selected one of an active test mode and a tri-state mode.

5. The multichip package defined in claim 1, wherein the test IO pin comprises a general-purpose IO pin that is coupled to the integrated circuit.

6. The multichip package defined in claim 1, wherein a first portion of the plurality of auxiliary integrated circuit components is coupled to a first set of general-purpose IO pins for the integrated circuit, and wherein a second portion of the plurality of auxiliary integrated circuit components that are different than the first portion is coupled to a second set of general-purpose IO pins for the integrated circuit that is different than the first set.

7. The multichip package defined in claim 1, further comprising:
multiplexing circuitry that is interposed between the plurality of auxiliary integrated circuit components and the test input-output pin.

8. A multichip package, comprising:
a plurality of integrated circuits; and
multiplexing circuitry that routes test signals to a selected one of the plurality of integrated circuits during testing.

9. The multichip package defined in claim 8, wherein the plurality of integrated circuits comprises a plurality of memory elements.

10. The multichip package defined in claim 8, further comprising:
an additional integrated circuit; and
an interposer on which the additional integrated circuit and the plurality of integrated circuits are mounted, wherein the multiplexing circuitry is formed within the interposer.

11. The multichip packaged defined in claim 8, further comprising:
an additional integrated circuit within which the multiplexing circuitry is formed.

12. The multichip package defined in claim 8, further comprising:
an additional integrated circuit that sends control signals directly to the plurality of integrated circuits during testing.

13. The multichip package defined in claim 8, further comprising:
an additional integrated circuit, wherein the multiplexing circuitry receives the test signals via general-purpose input-output (GPIO) pins of the additional integrated circuit during testing.

14. The multichip package defined in claim 13, wherein the additional integrated circuit receives active user signals via the GPIO pins during normal operation.

15. A method for operating a multichip package that includes a main integrated circuit die that is coupled to a plurality of auxiliary components, the method comprising:
selecting one of the plurality of auxiliary components for testing; and
sending test signals to the selected auxiliary component during testing while auxiliary components other than the selected auxiliary component in the plurality of auxiliary components are idle.

16. The method defined in claim 15, wherein selecting one of the plurality of auxiliary components for testing comprises sending select signals to the plurality of auxiliary components via dedicated select pins.

17. The method defined in claim 15, wherein selecting one of the plurality of auxiliary components for testing comprises sending control signals from the main integrated circuit die directly to the plurality of auxiliary components.

18. The method defined in claim 15, wherein sending the testing signals to the selected auxiliary component during testing comprises sending the test signals to the selected auxiliary component via general-purpose input-output (GPIO) pins of the main integrated circuit die, the method further comprising:
using the GPIO pins to convey active user signals to the main integrated circuit die during normal operation of the multichip package.

19. The method defined in claim 15, further comprising:
borrowing general-purpose input-output (GPIO) pins from the main integrated circuit die to convey the test signals via the borrowed GPIO pins to the plurality of auxiliary components during testing; and
returning the GPIO pins to the main integrated circuit die so that the main integrated circuit die receives data signals via the GPIO pins during normal operation.

20. The method defined in claim 15, wherein sending the test signals to the selected auxiliary component during testing comprises sending the test signals to the selected auxiliary component via a multiplexing circuit.
